(19) United States
(12) Patent Application Publication
(10) Pub. No.: US 2023/0260808 A1
(43) Pub. Date: Aug. 17, 2023

(54) HEATING SYSTEM AND METHOD FOR HEATING LARGE-SURFACE SUBSTRATES

(71) Applicant: SINGULUS TECHNOLOGIES AG, Kahl am Main (DE)

(72) Inventors: Bernhard CORD, Alzenau (DE); Sergiy BORODIN, Aschaffenburg (DE); Andreas LUDWIG, Aschaffenburg (DE); Emmerich Manfred NOVAK, Kloster Lehnin, OT Grebs (DE)

(21) Appl. No.: 18/011,483

(22) PCT Filed: Jun. 14, 2021
(86) PCT No.: PCT/EP2021/065955

§ 371 Date: Dec. 19, 2022

(30) Foreign Application Priority Data
Jun. 30, 2020 (DE) 10 2020 208 184.0

(51) Int. Cl. H01L 21/67; H01L 21/687

(52) U.S. Cl. CPC H01L 21/67115; H01L 21/67248; H01L 21/68785; H01L 21/6875

(57) ABSTRACT

The present invention relates to a heating system and to a method for heating large-surface substrates.

The present invention relates to a heating system as well as a method for heating large-area substrates.

For various processes, for example in thin-film photovoltaics, it is necessary to heat large-area substrates with dimensions of, for example, 1.5 m×2 m to temperatures of, for example, 700° C. Due to the increased temperature, the stability of the substrate can be reduced; in particular when glass is used, this occurs when the glass softening point is exceeded. Thus, it is necessary that the substrate is supported over its entire surface or partially by a carrier plate during the heating process. In the simplest case, the substrate is usually placed on a directly or indirectly heated heating plate. However, due to slight unevenness of the substrate, for example, this can result in a locally different contact between the substrate and the heating plate, which influences the heating process and leads to considerable temperature inhomogeneities in the substrate. These local temperature differences can have a disadvantageous effect on the process or lead to the destruction of the substrate due to thermal stresses. These problems occur more frequently in particular when substrates with poor thermal conduction (for example glass) are heated very rapidly, for example at rates of 5 K/s.

In order to address this problem, DE 199 36 081 A1 suggests heating through a so-called transparency body, which comprises a specific transmission and a specific absorption for the relevant electromagnetic radiation. This is intended to heat the substrate partly directly by means of electromagnetic radiation passing through the transparency body and partly indirectly by means of thermal conduction by contact with the transparency body, which heats up by means of absorption. The transparency body can comprise a spacer, against which the substrate rests. However, this type of heating is disadvantageous in that, i.a., it is difficult to control precisely. However, complete temperature equality between the substrate to be heated and the transparent carrier body can only be achieved if narrow tolerances are met. This equilibrium is already disturbed, for example, by a change in the thickness ratios or the absorptivity of the substrate. Such a change in absorptivity occurs, for example, when reflective or highly absorbent layers are applied to the substrate.

Therefore, there is a need for heating systems for large-area substrates that also allow higher temperature differences between the carrier and the substrate.

It is therefore an object of the present invention to provide an improved heating system and an improved method for heating large-area substrates, which overcome the disadvantages of the prior art.

This object is achieved with a heating system according to claims 1, 2 and 6 and with a method according to claims 26 and 27.

Accordingly, in accordance with a first aspect, the present invention provides a heating system for heating large-area substrates. The heating system comprises a susceptor plate having an upper side and a lower side, wherein the susceptor plate is nontransparent to infrared radiation. Furthermore, the heating system comprises a plurality of spacers above the susceptor plate, which consist of a material having a low thermal conductivity. Finally, the heating system comprises an infrared radiation source which is arranged and configured to heat the lower side of the susceptor plate by means of infrared radiation.

The invention is based, i.a., on the fact that the susceptor plate is indirectly heated by means of infrared radiation from the infrared radiation source and then transfers the absorbed energy to the substrate to be heated by means of thermal radiation and/or thermal conduction, wherein homogeneous heating can be achieved due to the spacers, since the problem described at the beginning cannot occur, namely the problem that due to slight unevenness of the substrate a locally different contact between the substrate and the heating plate occurs, which influences the heating process and leads to considerable temperature inhomogeneities in the substrate. Since the susceptor plate is nontransparent to infrared radiation, direct heating of the substrate by the infrared radiation source cannot occur. The good thermal conductivity, in particular in the lateral direction, of the susceptor plate improves the homogeneity of the radiation emitted by the susceptor plate, so that any small inhomogeneities of the infrared radiation source can be compensated for. The heating of the substrate by the heated susceptor plate by means of thermal radiation and/or thermal conduction can therefore be controlled very precisely.

In the context of the present invention, large-area substrates mean substrates of an area of at least 0.7 m², preferably at least 1 m², more preferably at least 2 m² and particularly preferably at least 3 m². Substrates can be, for example, coated or uncoated glass panes, coated or uncoated silicon wafers with or without electronic components. Basically, however, the invention is suitable for any substrates.

According to a second aspect, the present invention is directed to a heating system for heating large-area substrates. The heating system comprises a susceptor plate having an upper side and a lower side, as well as a plurality of spacers above the susceptor plate, which consist of a material having a low thermal conductivity. Furthermore, the heating system comprises an infrared radiation source which is arranged and configured to heat the lower side of the susceptor plate by means of infrared radiation. The susceptor plate is to be constructed of such a material and to be dimensioned such that, during the heating test defined further below using the reference substrate defined further below, the susceptor plate is heated such that the maximum heating rate of the susceptor plate during the first 20 s of heating is greater by at least a factor of 4 than the maximum heating rate of the reference substrate during the first 20 s of heating. This large temperature gradient reflects a very rapid heating of the susceptor plate, which in turn heats the substrate with a time delay by means of thermal radiation and, as the case may be, thermal conduction through the heat-conducting gas present between the susceptor plate and the substrate (preferably at atmospheric pressure).

If there is no vacuum between the upper side of the susceptor plate and the substrate to be heated, the heating of the substrate is usually based on a combination of thermal radiation, direct thermal conduction at contact points between the susceptor plate and the substrate, and thermal conduction through the fluid located between the susceptor plate and the substrate. In the case of small distances, the latter is relatively strongly dependent on the distance, so that this component possibly leads again to inhomogeneities in the heating. Therefore, it is preferred that the distance between the susceptor plate and the substrate is selected such that the thermal conduction becomes very small and also depends only very weakly on the distance. Therefore, it is preferred that this distance is at least 1 mm and particularly preferred at least 2 mm or that the spacers protrude at least 2 mm from the upper side of the susceptor plate. More preferably, this distance is at least 2.5 mm and particularly preferably at least 3 mm.

In the course of detailed simulations and experiments, it became apparent that the influence of the clearance between the susceptor plate and the substrate on the heating process is negligible from a minimum distance of around 2 mm. In other words, from a minimum distance of around 2 mm, distance variations caused, for example, by substrate unevenness no longer play a role, so that very homogeneous heating can be achieved with accordingly dimensioned spacers.

In order to keep the possible disturbance of the heating process by the spacers low, their geometry should be kept as small as possible, so that, on the other hand, it is preferred that the spacers protrude at most 10 mm, more preferably at most 8 mm and particularly preferably at most 5 mm from the upper side of the susceptor plate.

The spacers can be arranged directly on the upper side of the susceptor plate or connected to it. Alternatively, the spacers can also be arranged at a distance from the upper side of the susceptor plate above the susceptor plate. For example, the spacers can be held by corresponding carrier strips or a grating extending above the susceptor plate. However, the spacers arranged above the susceptor plate are preferably located exclusively above or on the upper side of the susceptor plate and preferably do not extend into the susceptor plate and in particular do not extend through it. Rather, the spacers are structures which preferably extend exclusively between the upper side of the susceptor plate and the lower side of the substrate.

With respect to the aims intended to be achieved by the present invention, it is further preferred that the spacers are static structures which are permanently present above the susceptor plate. In particular, the spacers are to be present above the susceptor plate during processing the substrate and in particular during the heating process, and the substrates are to be supported on the spacers during the heating process.

Furthermore, for the purpose of a rapid heating process of the substrate, it is preferred that the temperature of the susceptor plate during the heating process is significantly higher than that of the substrate. Accordingly, the susceptor plate preferably is constructed of such a material and dimensioned such that, during the heating test defined further below using the reference substrate defined further below, the susceptor plate is heated such that the maximum temperature difference between the susceptor plate and the reference substrate during the first 90 s of heating is at least 100 K, preferably at least 200 K, more preferably at least 300 K, even more preferably at least 400 K and particularly preferably at least 500 K. These high initial temperature differences also reflect the very rapid heating of the susceptor plate and the associated high radiation power of the susceptor plate onto the substrate.

In the context of the present invention, infrared radiation is understood to be the wavelength range between 0.5 μm and 10.0 μm. Accordingly, the susceptor plate preferably has a transmission of less than 10%, more preferably less than 5%, even more preferably less than 3% and particularly preferably less than 1%, for electromagnetic radiation in the entire wavelength range between 0.5 μm and 10.0 μm. It may be sufficient if these transmission values are achieved as an average over the entire wavelength range between 0.5 μm and 10.0 μm, since ultimately only the cumulative heating power is relevant. However, it is preferred that these transmission values are actually achieved over the entire wavelength range between 0.5 μm and 10.0 μm for each individual wavelength. If the infrared radiation source only emits infrared radiation of a particular wavelength band (or a plurality of bands), it is sufficient that the susceptor plate has said transmission values for infrared radiation within this wavelength band (or these bands), since an increased transmission for radiation that is not emitted is harmless.

The high absorptivity of the susceptor plate causes initially exclusive heating of the susceptor plate and then heating of the substrate due to the strongly increasing temperature of the susceptor plate. The high absorptivity of the susceptor plate and the indirect heating of the substrate are defined by measuring the heating temperatures of the susceptor plate and the substrate. In this connection, it is also advantageous that the susceptor plate has a low thickness and heat capacity in order to achieve a rapid heating process.

It is further preferred that the susceptor plate has an absorptivity of at least 45%, more preferably at least 50% and particularly preferably at least 55%, for electromagnetic radiation in the entire wavelength range between 0.5 μm and 10.0 μm. Here, too, a corresponding absorption on average may suffice. However, it is preferred that these absorptivities are achieved for all wavelengths. The absorption of the susceptor plate can be further increased by appropriate measures, such as, for example, structuring the surface or a higher surface roughness or coating, for example with graphite. In this case, even absorptivities of at least 65%, more preferably at least 75% and particularly preferably at least 85% are possible.

It is further preferred that the susceptor plate has an emissivity of at least 45%, more preferably at least 50% and particularly preferably at least 55%, for electromagnetic radiation in the entire wavelength range between 0.5 μm and 10.0 μm. Here, too, a corresponding emission on average may suffice. However, it is preferred that these emissivities are achieved for all wavelengths. The emission of the susceptor plate can be further increased by appropriate measures, such as, for example, structuring the surface or a higher surface roughness or coating, for example with graphite. In this case, even emissivities of at least 65%, more preferably at least 75% and particularly preferably at least 85% are possible.

The aforementioned values for transmission, absorption and emission can generally apply to the susceptor plate. However, with respect to the functionality of the susceptor plate, it is particularly desirable that the absorptivities are achieved for the lower side and the emissivities for the upper side of the susceptor plate. The aforementioned transmission values should particularly apply to a transmission directed from the bottom to the top. (Analogously, of course, this applies vice versa with respect to the optional susceptor plate above the substrate, cf. below).

According to a third aspect, the present invention is directed to a heating system for heating large-area substrates, which comprises a susceptor plate having an upper side and a lower side, a plurality of spacers above the susceptor plate and a heating source which is arranged directly at or in the susceptor plate and configured to directly heat the susceptor plate. The plurality of spacers preferably consist of a material having a low thermal conductivity, wherein the spacers protrude at least 1 mm, preferably at least 2 mm and particularly preferably at least 3 mm from the upper side of the susceptor plate.

Since in the case of this aspect of the invention the heating of the susceptor plate is not performed by means of infrared radiation, it is not necessary for this aspect that the susceptor plate is nontransparent to infrared radiation. Preferably, however, no image of the heat source geometry should be generated in the temperature distribution of the substrate. The heat source can be, for example, a resistance heater integrated into the susceptor plate. The resistance heater is preferably configured such that the surface of the susceptor plate comprises a homogeneous temperature distribution, wherein the thermal conduction within the susceptor plate also improves the homogeneous temperature distribution.

The susceptor plate of this third aspect of the invention also preferably consists of a material that corresponds to the heating tests defined above for the other aspects of the invention.

The preferred features described below are relevant to all three aspects of the present invention described above.

The thermal conductivity of the spacers is preferably less than 15 W/m/K, more preferably less than 12 W/m/K, more preferably less than 6.0 W/m/K, even more preferably less than 4.5 W/m/K and particularly preferably less than 3.0 W/m/K, in the entire temperature range between 20° C. and 1,000° C. Since the materials used for the spacers can also be anisotropic, it is in particular preferred that the thermal conductivity of the spacers in the direction perpendicular to the substrate plane is preferably less than 15 W/m/K, more preferably less than 12 W/m/K, more preferably less than 6.0 W/m/K, even more preferably less than 4.5 W/m/K and particularly preferably less than 3.0 W/m/K, in the entire temperature range between 20° C. and 1,000° C. The thermal conductivity of the spacers can be determined by usual methods such as the laser flash method, the transient hot bridge method or by means of heat flow meters (for example using the λ-meter EP500e from Lambda-Meßtechnik GmbH Dresden). The needle probe method according to ASTM D5334-08 is a particularly preferred measurement method in the context of the present invention.

Therefore, it is preferred that the spacers consist of, for example, quartz, glass or glass ceramic. CFC or other carbon-containing materials are also suitable as materials for the spacers.

These spacers can be tubes, rods, pyramidal structures or the like. As will be explained in detail below, tubes or rods can extend along the transverse and/or longitudinal direction of the substrate and form a support grate or grating. Alternatively, isolated, local spacers can be provided to further minimize the support area, for example spherical, pyramidal or conical structures that support the substrate in a grid.

Preferably, the spacers should be shaped such that the support area or the contact area between the substrate and the spacer is minimized. Preferably, the total (summed) contact area between the substrate and all spacers is at most 5%, more preferably at most 1%, particularly preferably at most 0.1% of the substrate surface. The thicker the substrate, the better temperature inhomogeneities within the substrate can be compensated for by lateral thermal conduction in the substrate. Therefore, a particularly small support area is advantageous in the case of particularly thin substrates. It is therefore preferred that the width of the contact line of spacers extending continuously along the transverse and/or longitudinal direction of the substrate is smaller than 50%, preferably smaller than 20% and particularly preferably smaller than 10% of the substrate thickness. In the case of isolated spacers, it is preferred that the diameter or the maximum dimension of the support area of a spacer is smaller than 50%, preferably smaller than 20% and particularly preferably smaller than 10% of the substrate thickness.

Minimization of the contact area is also achieved, for example, by a high modulus of elasticity, i.e. low elastic deformation, and/or low surface roughness of the contact bodies. Hence, the modulus of elasticity of the spacer material is preferably at least 50 GPa, more preferably at least 60 GPa, even more preferably at least 70 GPa. The surface roughness of the spacers is preferably at most 0.05 μm, more preferably at most 0.03 μm and even more preferably at most 0.02 μm. This further minimizes the input due to thermal conduction and temperature gradients caused thereby.

In order to minimize the disturbance of the energy transfer from the susceptor plate to the substrate by means of thermal radiation, it is advantageous that the spacers shade as little area of the substrate as possible. It is therefore preferred that the total projected area of all spacers (projected perpendicularly to the substrate surface) is at most 10%, preferably at most 6%, particularly preferably at most 3% of the substrate surface.

It is further preferred to provide a plurality of spacers to support the substrate as uniformly as possible. This is in particular relevant in the case of glass substrates and heating beyond the softening point. In order to prevent deflection of the heated substrate caused thereby to as great an extent as possible, it is preferred that the maximum unsupported distance between two spacers is smaller than 10 cm, more preferably smaller than 5 cm and particularly preferably smaller than 3 cm. In corresponding simulations for spacers extending parallel to each other, it has been found that when a glass plate of a thickness of 2 mm is supported on spacers at a distance of 5 cm for a time of 5 min, a maximum deflection of 0.2 mm results, which is considered to be tolerable. Analogous calculations were performed for discrete support points in a regular square pattern. Here, a diagonal of the square pattern (i.e. again the unsupported distance) of at most 5 cm provided good results.

The thickness of the susceptor plate is preferably smaller than 5 mm, more preferably smaller than 3 mm and particularly preferably smaller than 2 mm. For example, plates made of fiber-reinforced carbons (so-called CFC materials) can be used.

The upper side of the susceptor plate preferably comprises an area of at least 0.7 m², more preferably at least 1 m², more preferably at least 2 m² and particularly preferably at least 3 m².

In addition to the infrared radiation source or the heating source, a (further) infrared radiation source can be provided which is arranged and configured to heat the upper side of the susceptor plate and/or the substrate by means of infrared radiation. Particularly preferably, also from this side heating is performed indirectly by means of a susceptor plate. It is therefore further preferred that a further susceptor plate having an upper side and a lower side is provided, wherein the susceptor plate is nontransparent to infrared radiation. Furthermore, preferably a (further) infrared radiation source is provided which is arranged and configured to heat the upper side of the further susceptor plate by means of infrared radiation. The properties described above with respect to the lower susceptor plate also preferably apply to the upper susceptor plate, in particular also with respect to the optical parameters and the heating behavior.

In order to ensure that the substrate is heated as homogeneously as possible, it is preferred that the (upper and/or lower) susceptor plate has a lateral thermal conductivity within the susceptor plate plane of at least 10 W/m/K, more preferably at least 30 W/m/K and particularly preferably at least 50 W/m/K, in the entire temperature range between 20° C. and 1,000° C.

The present invention is further directed to a method of heating a large-area substrate using the heating system described above (all three aspects). The method comprises placing a large-area substrate into the heating system such that the substrate is supported on the spacers. Furthermore, the method comprises heating the susceptor plate, whereby the substrate supported on the spacers is then heated primarily by means of thermal radiation.

Furthermore, the present invention is directed to a method of heating a large-area substrate comprising the steps of:
providing a heating system comprising a susceptor plate having an upper side and a lower side, a plurality of spacers above the susceptor plate, which consist of a material having a low thermal conductivity, and an infrared radiation source which is arranged and configured to heat the lower side of the susceptor plate by means of infrared radiation;
placing a large-area substrate into the heating system such that the substrate is supported on the spacers; and
heating the susceptor plate, preferably while the substrate is stationarily supported on the spacers.

The susceptor plate is heated using the infrared radiation source preferably such that the maximum heating rate of the susceptor plate during the first 20 s of heating is greater by at least a factor of 4, preferably at least a factor of 6, more preferably at least a factor of 10, than the maximum heating rate of the substrate during the first 20 s of heating. Preferably, the maximum temperature difference between the susceptor plate and the substrate during the first 90 s of heating is at least 100 K, preferably at least 200 K, more preferably at least 300 K, even more preferably at least 400 K and particularly preferably at least 500 K.

The substrate preferably has an area of at least 0.7 m², more preferably at least 1 m², even more preferably at least 2 m² and particularly preferably at least 3 m².

The susceptor plate is preferably heated to a temperature of at least 600° C., more preferably at least 800° C. and particularly preferably at least 1,000° C.

The substrate is heated over its entire surface by the heated susceptor plate primarily by means of thermal radiation, wherein the heating of the substrate is performed at a rate of at least 2 K/s, more preferably at least 3 K/s and particularly preferably at least 4 K/s. Furthermore, the heating rate is preferably less than 18 K/s, more preferably less than 15 K/s and particularly preferably less than 10 K/s. In particular, according to the invention, a high initial heating rate of the susceptor plate is advantageous in order to rapidly ensure a high energy transfer from the susceptor plate to the substrate. It is therefore preferred that the susceptor plate is heated to a temperature of at least 300° C., preferably at least 400° C. and particularly preferably at least 500° C., during the first 20 s of heating.

Preferably, the substrate is heated to a temperature of at most 700° C., more preferably at most 650° C. and particularly preferably at most 600° C. Preferably, the substrate is heated to a temperature of at least 300° C., more preferably at least 400° C. and particularly preferably at least 500° C.

The heating process is preferably performed in the presence of a process gas. The gas can be an inert gas, e.g. nitrogen or argon, a reactive gas or a mixture of an inert gas and a reactive gas. A gas pressure of at least 20 mbar, more preferably at least 100 mbar, even more preferably at least 200 mbar and particularly preferably atmospheric pressure prevails between the susceptor plate and the substrate during the heating process.

The distance between the upper side of the susceptor plate and the lower side of the substrate is preferably at least 1 mm, more preferably at least 2 mm and particularly preferably at least 3 mm. Furthermore, the distance between the upper side of the susceptor plate and the lower side of the substrate is preferably at most 10 mm, more preferably at most 8 mm and particularly preferably at most 5 mm.

As already explained, the minimum distance of 2 mm leads to particularly homogeneous heating within the substrate. In this context, it is preferred that the substrate is homogeneously heated during the entire heating process such that the temperature difference occurring in the substrate surface in the area of a spacer is at most 75 K, preferably at most 50 K and particularly preferably at most 25 K during the entire heating process. This can be measured, for example, with an infrared camera. For example, an area of 50 mm×50 mm comprising, as symmetrically as possible, at least one support area on at least one spacer can be evaluated with the aid of an infrared camera. Of all temperatures determined within this area, the maximum difference is determined at each measurement time. Preferably, the maximum difference for all measurement times should be at most 75 K, more preferably at most 50 K and particularly preferably at most 25 K. In corresponding simulations, it has been found that discrete spacers with support areas that are as punctiform as possible have a clear advantage in this respect. This is due, among other things, to the fact that the shading is only punctiform and a local inhomogeneity of the temperature distribution caused by a discrete spacer can be compensated for from all sides by thermal conduction within the substrate, whereas a linear disturbance can only be compensated for by thermal conduction transverse to the line.

Preferably, the total contact area between the substrate and all spacers is at most 5%, preferably at most 1%, particularly preferably at most 0.1% of the substrate surface. As already stated above, it is preferred that the width of the contact line of spacers extending continuously along the transverse and/or longitudinal direction of the substrate is smaller than 50%, preferably smaller than 20% and particularly preferably smaller than 10% of the substrate thickness. In the case of isolated spacers, it is preferred that the diameter or the maximum dimension of the support area of a spacer is smaller than 50%, preferably smaller than 20% and particularly preferably smaller than 10% of the substrate thickness.

Preferably, the total projected area of all spacers is at most 10%, preferably at most 6%, particularly preferably at most 3% of the substrate surface.

Preferably, the maximum unsupported distance between the support areas of two spacers is at most 10 cm, preferably at most 5 cm, particularly preferably at most 3 cm.

Also within the scope of the methods according to the invention, the heating system can further comprise a further susceptor plate having an upper side and a lower side, and a further infrared radiation source being arranged and configured to heat the upper side of the further susceptor plate by means of infrared radiation. In this case, the large-area substrate is placed into the heating system such that the substrate between the two susceptor plates is supported on the spacers. The distance between the lower side of the further susceptor plate and the upper side of the substrate is also preferably at least 1 mm, more preferably at least 2 mm.

The present invention describes an advantageous heating system as well as an advantageous heating method for the case that a large-area substrate (e.g., a large-area glass pane) rests on a susceptor plate, which is rapidly heated by, e.g., IR radiators, wherein a homogeneous temperature distribution is achieved within the large-area substrate. In this heating system and heating method, various features according to the invention work together synergistically. For example, the spacers, particularly in the case of a distance of at least 2 mm, enable a uniform energy supply, since, from this minimum distance, variations in the clearance have no significant effect on the thermal conduction through the process gas. In order to enable high heating rates of the substrate in the case of these distances, very rapid heating of the susceptor plate is provided, which is reflected in correspondingly large initial temperature differences and heating rate ratios between the susceptor plate and the substrate. In turn, supporting the substrate on the spacers can entail that the substrate (e.g., the glass pane) deflects between the spacers when the substrate is heated in the range of the glass transition temperature and the heated substrate is supported for an extended period of time. This can be effectively avoided in that a corresponding maximum distance between the spacers is defined depending on the temperature (and the viscosity resulting therefrom) and the supporting time.

Preferred embodiments of the present invention are described in more detail below with reference to the Figures, in which:

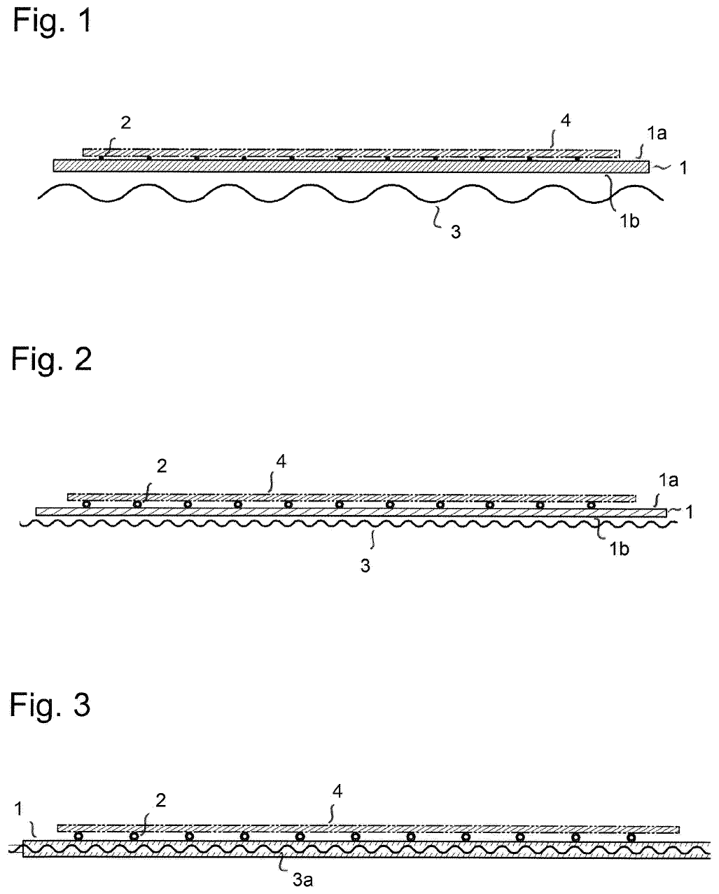

FIG. 1 shows a schematic sectional view through a heating system according to a preferred embodiment of the present invention;

FIG. 2 shows a schematic sectional view through a heating system according to a further preferred embodiment of the present invention;

FIG. 3 shows a schematic sectional view through a heating system according to a further preferred embodiment of the present invention;

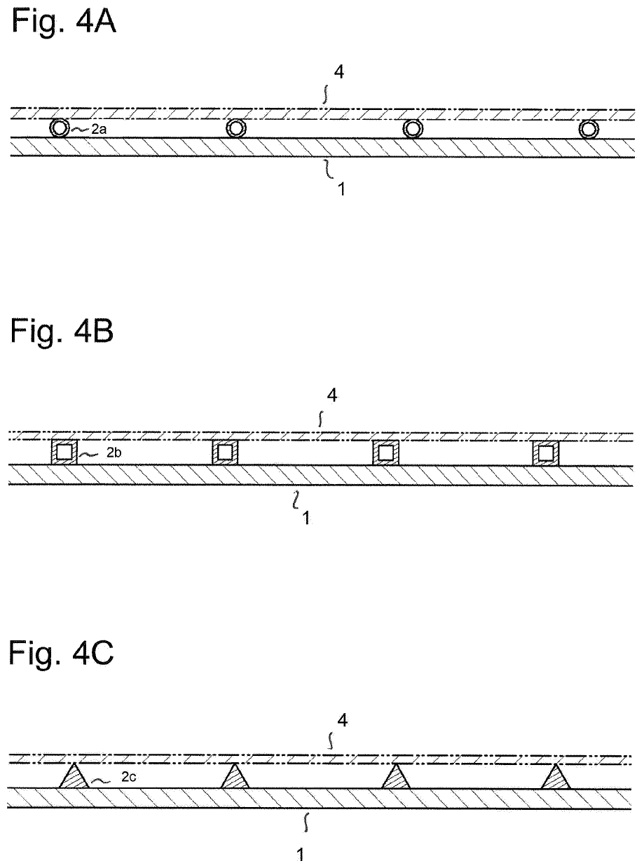

FIG. 4A schematically shows the arrangement of spacers according to a first preferred embodiment;

FIG. 4B schematically shows the arrangement of spacers according to a second preferred embodiment;

FIG. 4C schematically shows the arrangement of spacers according to a third preferred embodiment;

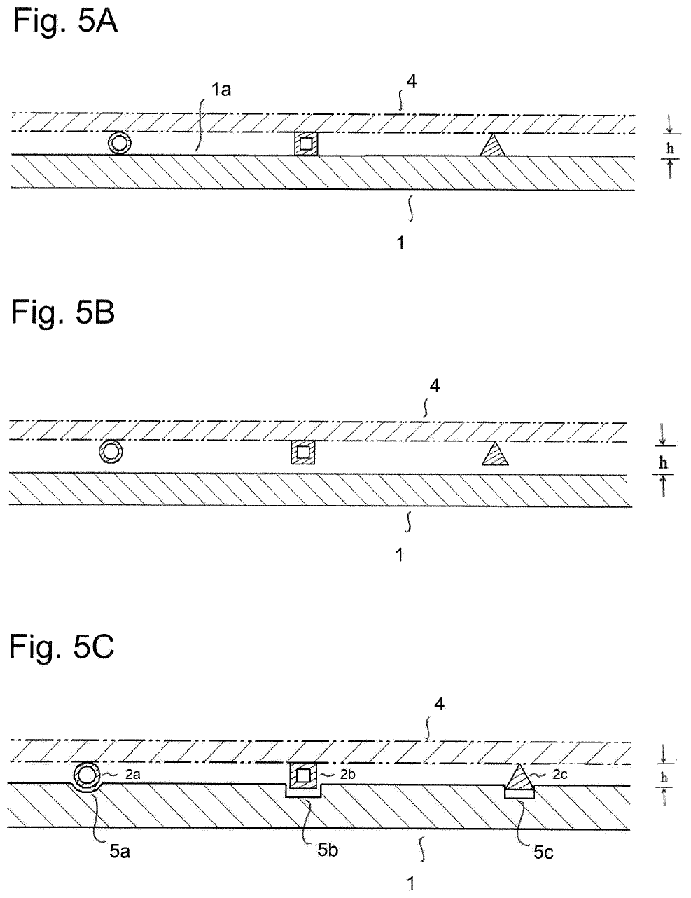

FIG. 5A schematically shows the arrangement of the spacers according to FIGS. 4A-C according to a first preferred embodiment;

FIG. 5B schematically shows the arrangement of the spacers according to FIGS. 4A-C according to a second preferred embodiment;

FIG. 5C schematically shows the arrangement of the spacers according to FIGS. 4A-C according to a third preferred embodiment;

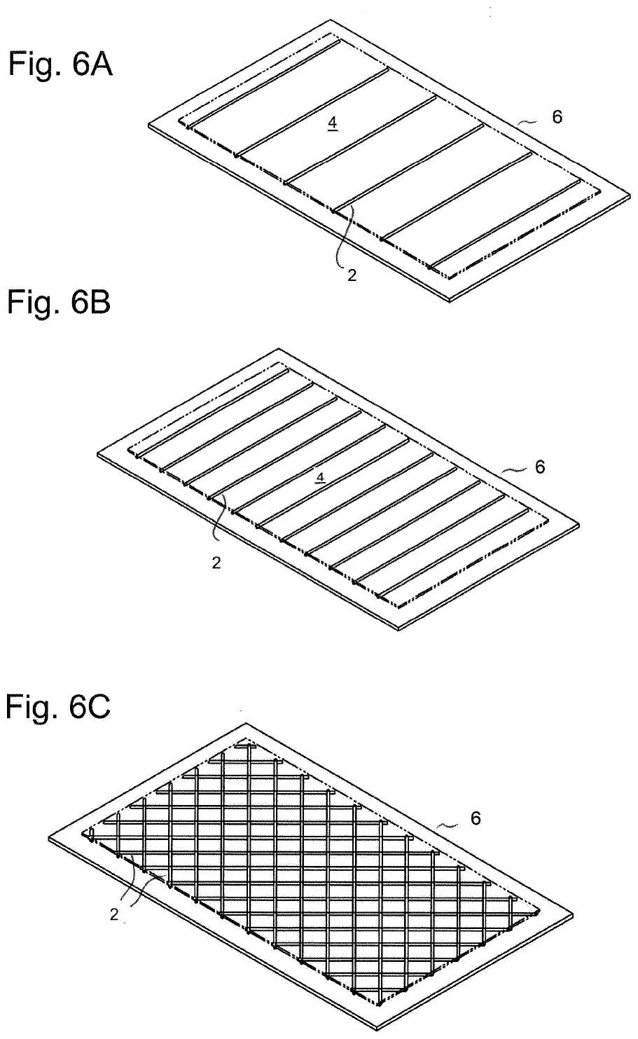

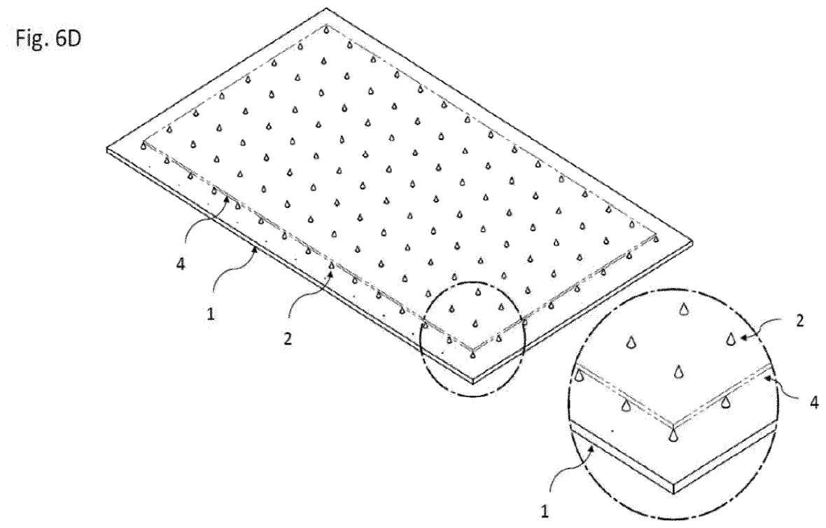

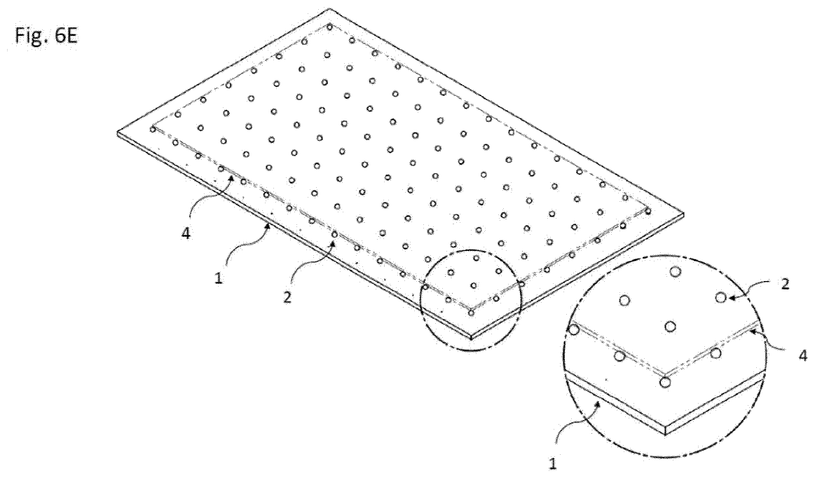

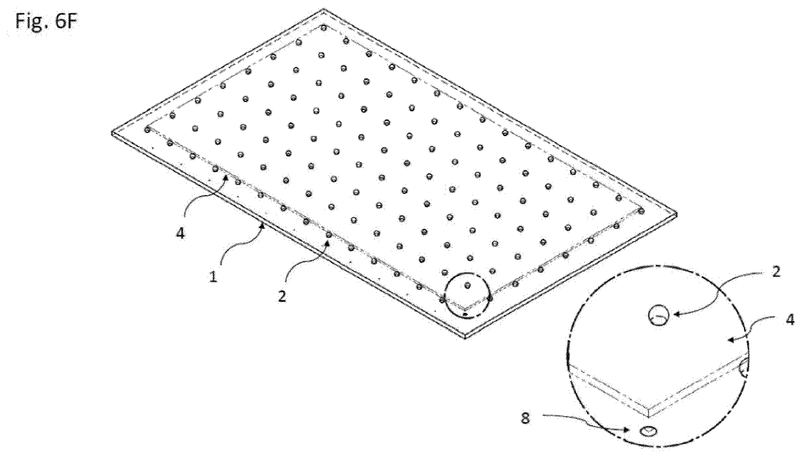

FIG. 6A shows a schematic perspective view of a heating system according to a preferred embodiment of the present invention;

FIG. 6B shows a schematic perspective view of a heating system according to a further preferred embodiment of the present invention;

FIG. 6C shows a schematic perspective view of a heating system according to a further preferred embodiment of the present invention;

FIG. 6D shows a schematic perspective view of a heating system according to a further preferred embodiment of the present invention;

FIG. 6E shows a schematic perspective view of a heating system according to a further preferred embodiment of the present invention;

FIG. 6F shows a schematic perspective view of a heating system according to a further preferred embodiment of the present invention;

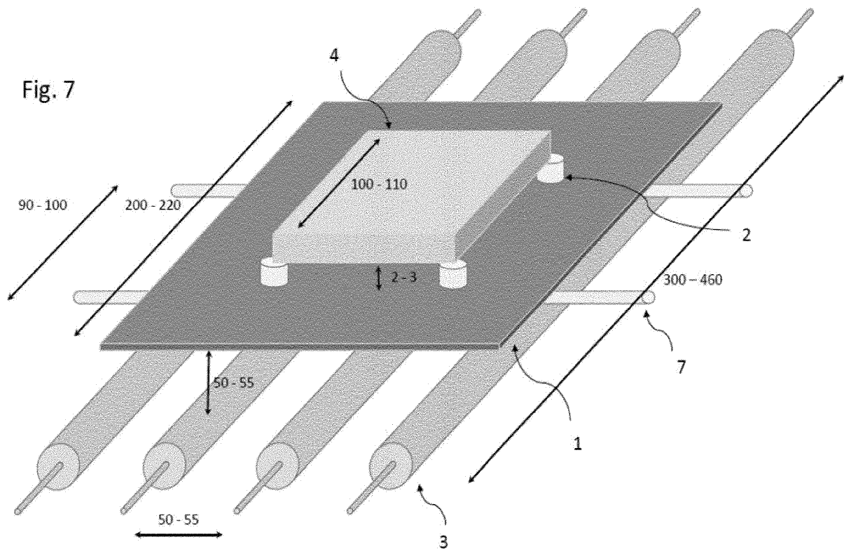

FIG. 7 schematically shows a measuring arrangement for the heating test;

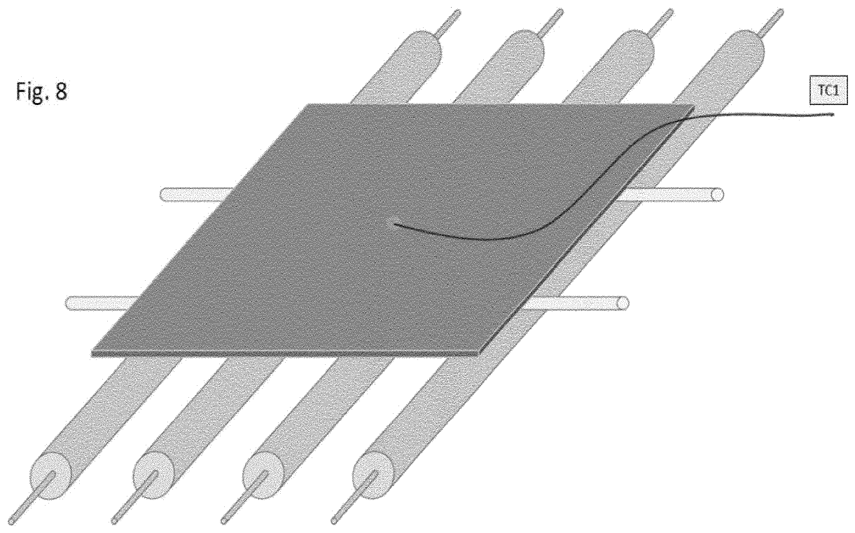

FIG. 8 schematically shows the placement of the thermocouple TC1 for the heating test;

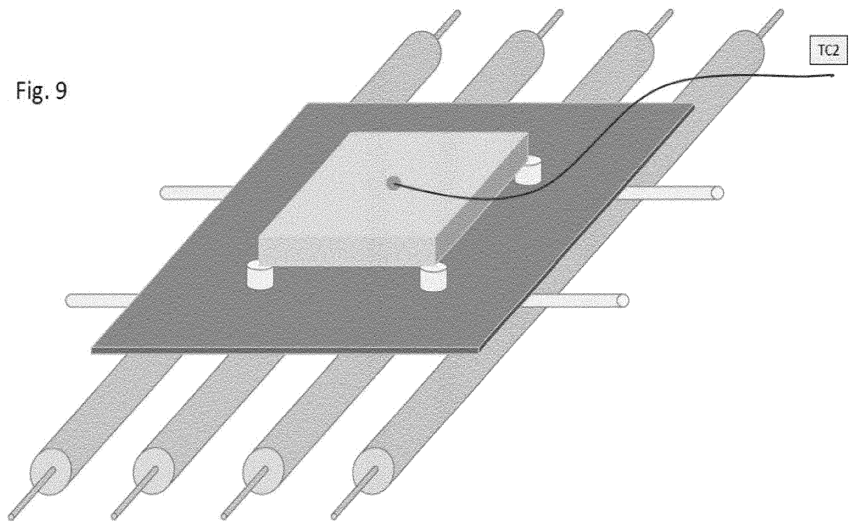

FIG. 9 schematically shows the placement of the thermocouple TC2 for the heating test;

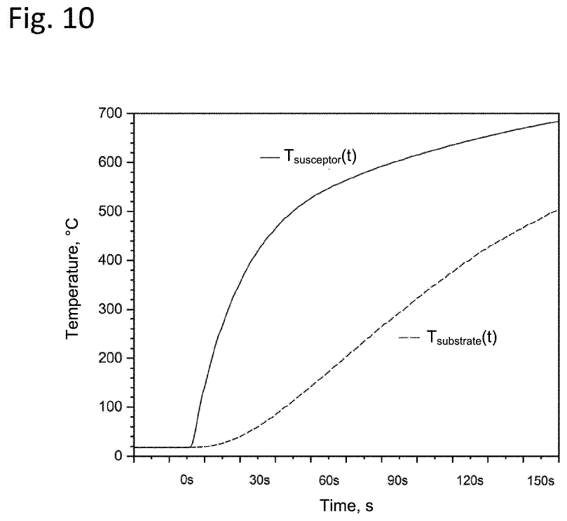

FIG. 10 shows the temperature profile over time of a susceptor plate and a substrate in the method according to the invention; and

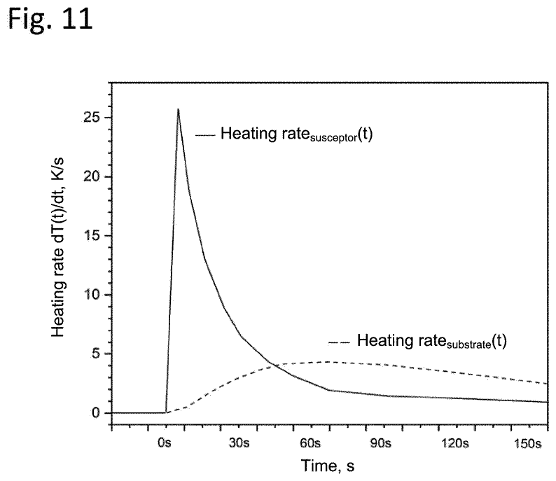

FIG. 11 shows the heating rates determined from the temperature profiles according to FIG. 10.

FIG. 1 shows a schematic sectional view through a heating system for heating large-area substrates according to a preferred embodiment of the present invention. The heating system comprises a susceptor plate 1 with an upper side 1a and a lower side 1b, wherein the susceptor plate 1 preferably is nontransparent to infrared radiation. A plurality of spacers 2 are arranged on the upper side 1a of the susceptor plate 1. A large-area substrate 4 is supported on the spacers 2. The spacers 2 preferably consist of a material having a low thermal conductivity in order to prevent direct thermal conduction from the susceptor plate 1 to the substrate 4 to as great an extent as possible.

An infrared radiation source 3 is schematically indicated below the susceptor plate 1, which is configured to heat the lower side 1b of the susceptor plate 1 by means of infrared radiation. The infrared radiation source 3 can be a single, extensive radiation source or an arrangement of several radiant heaters, for example several tubular IR radiators.

In this context, it is to be emphasized that the schematic illustration according to FIG. 1 is not to scale. In fact, the substrate 4 can have an area of several square meters, whereas the cross-sectional area of the individual spacers 2 is usually only a few square millimeters.

In FIG. 1, the spacers 2 are solid rods with a round cross-section. Alternatively, the spacers 2 can be in the form of a tube with an internal cavity, as shown in FIG. 2. Different variants of cross-sections of spacers 2a, 2b and 2c according to the invention are shown in FIGS. 4A-C. For example, rods with a rectangular or triangular cross-sectional profile can also be used (cf. FIGS. 4B and C) instead of a tube 2a with an internal cavity (cf. FIG. 4A). These rods 2b, 2c can also be hollow (cf. FIG. 4B) or solid (cf. FIG. 4C). Alternatively, the spacer 2c (cf. FIG. 4C) could also be pyramidal with a punctiform support area and the spacer 2b (cf. FIG. 4B) could be cylindrical with, for example, a circular support area.

In reality, usually one type of spacers will be decided upon and a plurality of such spacers will be arranged in a regular pattern with substantially constant distances. Exemplary arrangements are shown in FIGS. 6A-C. For example, rod-shaped spacers 2 can be arranged parallel to each other (cf. FIGS. 6A and 6B) or in a crossing pattern (cf. FIG. 6C) so that rectangular or square portions of the substrate 4 are each supported on all four sides. The distance between adjacent spacers 2 can be variable (cf. FIGS. 6A and 6B) and should be adapted to the deformability (e.g., the deflection) of the substrate.

The applicant has conducted comprehensive experiments concerning various spacers, which revealed that a number of parameters are relevant to the geometry and arrangement of the spacers. As already explained above, the spacers should preferably be dimensioned such that the substrate has a distance of at least 1 mm, more preferably at least 2 mm, from the susceptor plate in order to minimize the influence of the clearance on the energy transfer. In this way, homogeneous heating can be achieved.

Furthermore, the distance between adjacent spacers plays a role, as also already explained above. The higher the glass substrate is heated, the lower its viscosity becomes. In the range of the glass transition temperature, the substrate material begins to flow slowly. Depending on the achieved maximum temperature and depending on how long the substrate is supported on the spacers at this temperature, it can be determined which maximum distance between adjacent spacers still leads to tolerable deformations of the substrate. For arrangements according to FIGS. 6A and 6B, the applicant's analyses have shown in this respect that distances of at most 10 cm, preferably at most 5 cm and particularly preferably at most 3 cm, lead to good results for substrate materials, temperatures and supporting times common in practice. In the case of a grating-like arrangement of the spacers, as indicated in FIG. 6C, larger distances could also be tolerable if necessary.

In view of a direct thermal conduction through the spacers that is as low as possible, a contact area between the spacers and the substrate that is as small as possible is further advantageous. Therefore, for example, geometries as shown in FIGS. 4A and 4C are particularly advantageous, since in the case of cylinders, tubes or spacers with a triangular cross-section, the support area is more or less reduced to a support line. In corresponding experiments, the tubular spacer shown in FIG. 4A has proved to be particularly advantageous in this respect.

The geometry of the spacers further has an influence on the heating of the substrate by the thermal radiation, since the spacers shade the substrate in this respect. It is therefore also desired that the maximum cross-sectional area or projection of the spacers onto the substrate surface is as small as possible. In fact, as already mentioned above, the largest temperature inhomogeneities during heating were determined in the area of the spacers in experiments conducted by the applicant.

Furthermore, instead of the tubes or rods shown in FIGS. 6A-C, which extend continuously along the transverse and/or longitudinal direction of the substrate and form a support grate or grating, it is particularly preferred to provide isolated or discrete spacers, as exemplarily illustrated in FIGS. 6D-F, where conical or spherical spacers 2 are arranged in a regular square grid and form only punctiform support areas. Both with respect to the aforementioned shading of the substrate and with respect to the thermal conduction through the spacers, such discretely arranged spacers generate the smallest disturbances, which are also—as already explained—particularly well compensated for by a thermal conduction within the substrate. Of course, these discrete spacers do not have to be conical or spherical, as exemplarily illustrated, but can also be, for example, pyramidal or cylindrical. The arrangement in a square grid is not mandatory either, although a distribution of the spacers as regular as possible is to be preferred with respect to a disturbance as minimal as possible and unsupported distances as small as possible. When using spherical spacers, it is advisable to place the spheres in corresponding holes or recesses 8 so that they remain in their grid positions (cf. FIG. 6F).

By means of the spacers 2, it is preferably ensured that the distance between the upper side 1a of the susceptor plate 1 and the lower side of the substrate 4 is at least 2 mm. This can be achieved, for example, in that the spacers 2a, 2b, 2c are arranged directly on the upper side 1a of the susceptor plate 1, as shown in FIG. 5A, and protrude at least 2 mm from the upper side 1a of the susceptor plate 1. In this case, the distance h between the upper side 1a of the susceptor plate 1 and the lower side of the substrate 4 is defined by the thickness or height of the spacers 2a, 2b, 2c.

However, the spacers 2a, 2b, 2c do not have to rest on the upper side 1a of the susceptor plate 1, but can also be arranged, for example, at a distance above the susceptor plate 1 by other supporting mechanisms, as schematically illustrated in FIG. 5B. Here, too, the spacers 2a, 2b, 2c preferably protrude at least 2 mm from the upper side 1a of the susceptor plate 1. However, here the distance h between the susceptor plate and the substrate is greater than the thickness or height of the spacers 2a, 2b, 2c.

In a further alternative, as schematically shown in FIG. 5C, the spacers 2a, 2b, 2c can also be supported in corresponding recesses 5a, 5b, 5c in the upper side 1a of the susceptor plate 1, resulting in that the distance h between the susceptor plate and the substrate is smaller than the thickness or height of the spacers 2a, 2b, 2c.

As becomes apparent from these variants, a defined distance h between the susceptor plate and the substrate is to be ensured by the spacers protruding from the upper side of the susceptor plate. If, as shown in FIG. 5B, the spacers do not rest on the upper side 1a of the susceptor plate 1, the spacers are preferably rod-shaped and rest at their ends on a corresponding carrier frame 6. This is schematically illustrated in FIGS. 6A-C, where the spacers 2 extend from one edge of the carrier frame 6 across a rectangular cutout to the opposite edge of the carrier frame 6. In the rectangular cutout, the spacers 2 extend in a free-floating manner at a distance from the upper side 1a of the susceptor plate 1 (cf. FIG. 5B).

As explained at the beginning, according to a third aspect, the invention is directed to a heating system for heating large-area substrates, which comprises a susceptor plate having an upper side and a lower side, a plurality of spacers above the susceptor plate and a heating source which is arranged directly at or in the susceptor plate and configured to directly heat the susceptor plate. A preferred embodiment of this aspect of the invention is schematically illustrated in FIG. 3. In this embodiment, a heating coil 3a extends within the susceptor plate 1. Apart from that, the preferred features discussed in the context of the other Figures also apply to this embodiment.

The applicant has carried out the method according to the invention with a heating device according to the invention (with components corresponding to those described below in the context of the heating test, wherein a CFC plate with dimensions of 200 mm×200 mm×1 mm was used as the susceptor plate) and determined the temperature profiles over time of the susceptor plate of the heating device and a glass substrate. FIG. 10 shows the corresponding result. FIG. 11 shows the heating rates determined from the temperature profiles according to FIG. 10. As can be clearly seen, the susceptor plate is heated very rapidly by the heating device according to the invention, in particular during the first 20-30 s, wherein the corresponding heating rate passes through a maximum of greater than 25 K/s. The heating of the substrate takes place with a time delay at significantly lower heating rates: the maximum of the substrate heating rate—reached very much later—is less than 5 K/s. Accordingly, very large temperature gradients are formed between the susceptor plate and the substrate, which ultimately ensures effective, homogeneous and rapid heating of the substrate.

Heating Test

In the following, a heating test is described which can be used to check whether the maximum heating rate ratios according to the invention can be achieved with a susceptor plate and whether the susceptor plate has the properties according to the invention for electromagnetic waves, in particular IR radiation. For this purpose, the test setup schematically shown in FIG. 7 is used.

The test setup contains four regularly arranged short-wave IR radiators (having a length of 300-460 mm), with one or two filament(s) and a total power of 1.5-3 kW each. The circular tube radiators are coated with a reflective coating of gold, aluminum oxide, or QRC™ (quartz reflective coating), wherein R 50%. The IR radiators are marked with reference sign 3 in FIG. 7. The distance between the IR radiators 3 should be 50-55 mm.

Above the four IR radiators 3, the susceptor plate 1 to be tested is supported on two symmetrically placed tubes 7 such that the distance between the susceptor plate 1 and the IR radiators 3 is also 50-55 mm. Ceramic tubes made of aluminum oxide 10×1 or quartz tubes 10×1 (having a length of 300-500 mm) can be used for this purpose. The tubes 7 extend perpendicularly to the IR radiators 3 and have a distance of 90-100 mm from each other. If the susceptor plate to be tested is larger than 200 mm×200 mm (+20/−5), the plate is cut to this dimension and a plate section of 200 mm×200 mm (+20/−5) is measured.

A thermocouple TC1 is attached as centrally as possible to the upper side of the susceptor plate 1 by means of a high-temperature adhesive such as, for example, silver paint (cf. FIG. 8).

A glass substrate consisting of clear float glass and having a softening temperature of 510-600° C. and an area of 100 (+10/−5) mm×100 (+10/−5) mm and a thickness of 2 (+/−0.2) mm is used as the reference substrate for the heating test.

The reference substrate 4 is placed as centrally as possible with respect to the susceptor plate 1 onto four spacers 2, which are positioned at the four corners of the reference substrate 4 (cf. FIG. 7). The spacers 2 consist of ceramic having a height of 2-3 mm and a diameter of 8-10 mm.

A thermocouple TC2 is attached as centrally as possible to the upper side of the reference substrate by means of a high-temperature adhesive such as, for example, silver paint (see FIG. 9). For example, a type K sheathed thermocouple with a sheath material 1.4541 or 2.4816 and a sheath diameter of 0.5 (+/−0.2) mm can be considered for the thermocouples TC1 and TC2.

The heating test is performed in a closed room under a nitrogen atmosphere at 1,000 (+/−100) hPa, an oxygen partial pressure of maximum 10 ppm and a water dew point of at most −40° C. The test is started at room temperature, i.e., 23 (+/−3°) C.

At time t=0 s, the four IR radiators are simultaneously switched on with a power of 1.5 kW each (corresponding to a total radiant power of 6 kW) and the susceptor plate is heated with a constant radiant power until a temperature greater than or equal to 600° C. is measured on the reference substrate by means of the thermocouple TC2. The IR radiators are then switched off.

During the heating process, a temperature at the susceptor plate is measured by means of the thermocouple TC1 and a temperature at the reference substrate is measured by means of the thermocouple TC2 for a total of 90 s at each full second (i.e. for t=1 s, t=2 s, . . . , t=90 s). A heating rate for the susceptor plate and the reference substrate is determined from these measured temperatures for each full second by calculating the difference quotient (e.g., heating rate for the susceptor plate for t=1 s: (T_{TC1} (t=1 s)−T_{TC1} (t=0 s))/1 s).

According to the invention, the maximum heating rate of the susceptor plate during the first 20 s of heating is understood to be the maximum of the 20 values thus determined for the susceptor plate. According to the invention, the maximum heating rate of the reference substrate during the first 20 s of heating is understood to be the maximum of the values thus determined for the reference substrate.

According to the invention, the maximum temperature difference between the susceptor plate and the reference substrate during the first 90 s of heating is understood to be the maximum difference of the differences determined at the 90 times between the temperatures determined for each of the susceptor plate and the reference substrate.

1. A heating system for heating large-area substrates, comprising:
a susceptor plate having an upper side and a lower side, wherein the susceptor plate is nontransparent to infrared radiation;
a plurality of spacers above the susceptor plate, which consist of a material having a low thermal conductivity and project at least 1 mm from the upper side of the susceptor plate; and
an infrared radiation source which is arranged and configured to heat the lower side of the susceptor plate by means of infrared radiation, while a substrate is stationarily supported on the spacers.

2.-4. (canceled)

5. The heating system according to claim 1, wherein the spacers project at least 1 mm from the upper side of the susceptor plate.

6. A heating system for heating large-area substrates, comprising:
a susceptor plate having an upper side and a lower side;
a plurality of spacers above the susceptor plate, which consist of a material having a low thermal conductivity; wherein the spacers project at least 1 mm from the upper side of the susceptor plate; and
a heating source which is arranged directly at or in the susceptor plate and configured to directly heat the susceptor plate, while a substrate is stationarily supported on the spacers.

7. The heating system according to claim 6, wherein the spaces project at least 2 mm from the upper side of the susceptor plate.

8.-9. (canceled)

10. The heating system according to claim 1, wherein the thermal conductivity of the spacers in the direction perpendicular to the plane defined by the susceptor plate is less than 15 W/m/K in the entire temperature range between 20° C. and 1,000° C.

11. The heating system according to claim 1, wherein the spacers project at most 10 mm from the upper side of the susceptor plate.

12. The heating system according to claim 1, wherein the thickness of the susceptor plate is smaller than 5 mm.

13.-16. (canceled)

17. The heating system according to claim 1, further comprising a further susceptor plate having an upper side and a lower side, and a (further) infrared radiation source being arranged and configured to heat the upper side of the further susceptor plate by means of infrared radiation wherein the susceptor plate is nontransparent to infrared radiation.

18.-20. (canceled)

21. The heating system according to claim 1, wherein the susceptor plate and/or the further susceptor plate has a lateral thermal conductivity within the susceptor plate plane of at least 10 W/m/K in the entire temperature range between 20° C. and 1,000° C.

22. The heating system according to claim 1, wherein the spacers are arranged on the upper side of the susceptor plate.

23. The heating system according to claim 1, wherein the total contact area between the substrate and all spacers is at most 5% of the substrate surface.

24. The heating system according to claim 1, wherein the total projected area of all spacers is at most 15% of the substrate surface.

25. The heating system according to claim 1, wherein the maximum unsupported distance between the support areas of two spacers is at most 10 cm.

26. (canceled)

27. A method for heating a large-area substrate, comprising the steps of:
providing a heating system comprising a susceptor plate having an upper side and a lower side, a plurality of spacers above the susceptor plate, which consist of a material having a low thermal conductivity, and an infrared radiation source which is arranged and configured to heat the lower side of the susceptor plate by means of infrared radiation;
placing a large-area substrate into the heating system such that the substrate (4) is supported on the spacers; and
heating the susceptor plate, while the substrate is stationarily supported on the spacers.

28.-35. (canceled)

36. The method according to claim 27, wherein a gas pressure of at least 20 mbar prevails between the susceptor plate and the substrate.

37. The method according to claim 27, wherein the distance between the upper side of the susceptor plate and the lower side of the substrate is at least 1 mm and wherein the distance between the upper side of the susceptor plate and the lower side of the substrate is at most 10 mm.

38. (canceled)

39. The method according to claim 27, wherein the total contact area between the substrate and all spacers is at most 5% of the substrate surface.

40. The method according to claim 27, wherein the width of the contact line of spacers extending continuously along the transverse and/or longitudinal direction of the substrate is smaller than 50% of the substrate thickness.

41. The method according to claim 27, wherein the total projected area of all spacers is at most 10% of the substrate surface.

42. The method according to claim 27, wherein the maximum unsupported distance between the support areas of two spacers is at most 10 cm.

43.-44. (canceled)
